(19) United States
(12) Patent Application Publication
(10) Pub. No.: US 2025/0270425 A1
(43) Pub. Date: Aug. 28, 2025

(54) WATERPROOF ADHESIVE, PREPARATION METHOD OF WATERPROOF ADHESIVE, AND APPLICATION METHOD OF WATERPROOF ADHESIVE

(71) Applicant: ASUSTEK COMPUTER INC., TAIPEI (TW)

(72) Inventor: Yu-Kuang CHEN, TAIPEI (TW)

(21) Appl. No.: 18/671,461

(22) Filed: May 22, 2024

(30) Foreign Application Priority Data
Feb. 23, 2024 (CN) 202410201756.6

(51) Int. Cl. C09J 11/08; C09J 5/00; C09J 9/00; C09J 11/06

(52) U.S. Cl. CPC C09J 11/08; C09J 5/00; C09J 9/00; C09J 11/06

(57) ABSTRACT

A waterproof adhesive suitable for a flexible circuit board is provided. The waterproof adhesive includes a first agent and a second agent. The first agent includes a pressure sensitive adhesive and a polymer water-absorbing expansion material. The second agent includes a hardening agent and an end-capping reagent. The first agent and the second agent are mixed for use. A preparation method and an application method of the waterproof adhesive are further provided.

### CROSS-REFERENCE TO RELATED APPLICATION

This application claims the priority benefit of Chinese application serial No. 202410201756.6, filed on Feb. 23, 2024. The entirety of the above-mentioned patent application is hereby incorporated by reference herein and made a part of the specification.

### BACKGROUND OF THE INVENTION

### Field of the Invention

The disclosure relates to a waterproof adhesive, a preparation method of the waterproof adhesive, and an application method of the waterproof adhesive.

### Description of the Related Art

The main reason for the problem of key failure of a keyboard of a notebook computer is that in a high humidity environment, water vapor seeps into a membrane switch inside the keyboard, which causes oxidation of a metallic circuit inside the membrane switch, leading to the loss of functions of keys.

The main reason for water vapor entering the inside of the membrane switch is that an existing screen printing process requires multiple repeated printing steps. Multiple repeated printing steps easily lead to small defects such as narrower lines or residual bubbles in screen printing patterns, thereby weakening the sealing effect.

### BRIEF SUMMARY OF THE INVENTION

The disclosure provides a waterproof adhesive suitable for a flexible circuit board. The waterproof adhesive includes a first agent and a second agent. The first agent includes a pressure sensitive adhesive and a polymer water-absorbing expansion material. The second agent includes a hardening agent and an end-capping reagent.

The disclosure further provides a preparation method of a waterproof adhesive, suitable for preparing the above waterproof adhesive. The waterproof adhesive includes a first agent and a second agent. The first agent includes a pressure sensitive adhesive and a polymer water-absorbing expansion material, the second agent includes a hardening agent and an end-capping reagent, and the first agent and the second agent are mixed for use. The preparation method includes: mixing the polymer water-absorbing expansion material with water to produce a polymer material mixed solution; and adding the pressure sensitive adhesive and a solvent to the polymer material mixed solution to produce the first agent.

The disclosure further provides an application method of a waterproof adhesive, suitable for bonding a protective layer to a circuit board by the above waterproof adhesive. The waterproof adhesive includes a first agent and a second agent. The first agent includes a pressure sensitive adhesive and a polymer water-absorbing expansion material, and the second agent includes a hardening agent and an end-capping reagent. The application method includes: mixing the first agent with the second agent, and stirring a mixture of the first agent and the second agent for a preset time to produce a mixed adhesive material; coating the mixed adhesive material on the circuit board in a manner of screen printing; heating the circuit board under first baking conditions to shape the mixed adhesive material; and covering the circuit board with the protective layer, and heating the circuit board under second baking conditions to cure the waterproof adhesive.

The waterproof adhesive provided by the disclosure compensates for shortcomings of existing waterproof adhesives. In application, only one printing step (i.e. reducing process steps) is needed to bond the protective layer to the circuit board and provide a sealing effect, thereby effectively solving the problem of key failure of a keyboard and reducing the cost burden caused by key failure of the keyboard.

### BRIEF DESCRIPTION OF THE DRAWINGS

FIG. 1 is a flowchart of a preparation method of a waterproof adhesive provided in an embodiment of the disclosure;

FIG. 2 shows an embodiment of a preparation process for producing a polymer material mixed solution according to the disclosure;

FIG. 3 is a flowchart of an application method of a waterproof adhesive provided in an embodiment of the disclosure; and

FIG. 4 to FIG. 7 are schematic diagrams corresponding to the steps of the application method shown in FIG. 3.

### DETAILED DESCRIPTION OF THE EMBODIMENTS

Specific embodiments of the disclosure are described in more detail below with reference to schematic diagrams. Based on the following descriptions and the scope of the patent application, the advantages and features of the disclosure are clearer. It is to be noted that the figures are drawn in an extremely simplified form and imprecise proportion, and are only used for conveniently and clearly assisting in describing the objectives of the embodiments of the disclosure.

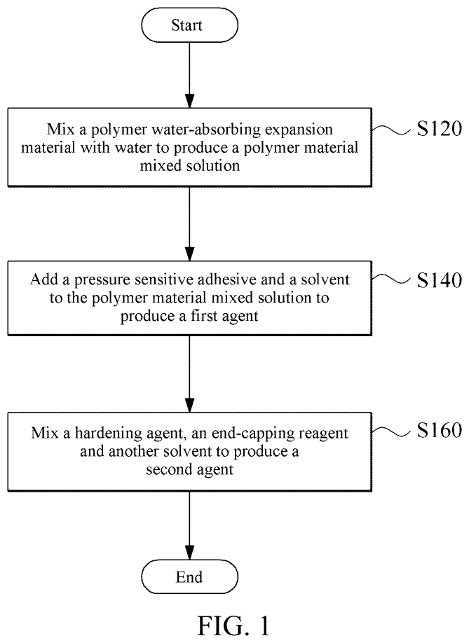

FIG. 1 is a flowchart of a preparation method of a waterproof adhesive provided in an embodiment of the disclosure.

The preparation method includes the following steps.

First, as described in step S120, a polymer water-absorbing expansion material is mixed with water to produce a polymer material mixed solution.

In an embodiment, the above polymer water-absorbing expansion material is selected from a group composed of hydrogenated cellulose, aquatic alginate, starch and combinations thereof.

Then, as described in step S140, a pressure sensitive adhesive and a solvent are added to the polymer material mixed solution to produce a first agent.

In an embodiment, the solvent used in the first agent is selected from a group composed of ethylene glycol monobutyl ether acetate, polyvinyl alcohol, acrylic acid, isopropanol, ethyl acetate and combinations thereof. In an embodiment, a hydrophilic-lipophilic balance (HLB) value of the solvent is 8-18 to provide a good mixing effect. The disclosure is not limited to this. In other embodiments, the pressure sensitive adhesive is directly mixed in the polymer material mixed solution, and the solvent is omitted.

Then, as described in step S160, a hardening agent, an end-capping reagent and another solvent are mixed to produce a second agent.

In an embodiment, the hardening agent includes cycloaliphatic amine and polyphenylmethane diisocyanate, and the end-capping reagent includes isocyanate. In an embodiment, the solvent used in the second agent is selected from a group composed of ethylene glycol monobutyl ether acetate, polyvinyl alcohol, acrylic acid, isopropanol, ethyl acetate and combinations thereof.

The waterproof adhesive prepared through the above preparation method includes two independently stored agents, namely the first agent and the second agent. In an embodiment, the first agent and second agent mentioned above are an agent A and an agent B in this technical field. The first agent includes a pressure sensitive adhesive and a polymer water-absorbing expansion material, and the second agent includes a hardening agent and an end-capping reagent. In an embodiment, the first agent further includes a solvent, and the solvent is selected from a group composed of ethylene glycol monobutyl ether acetate, polyvinyl alcohol, acrylic acid, isopropanol, ethyl acetate and combinations thereof.

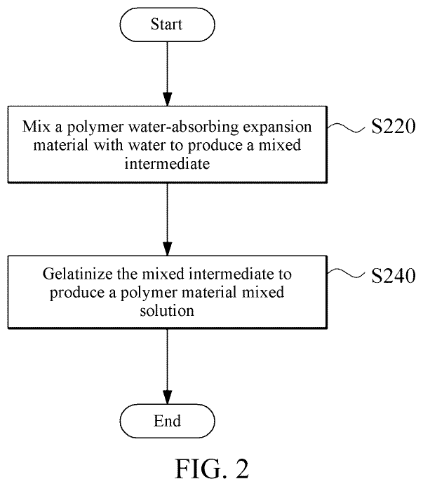

Referring to FIG. 2 together, FIG. 2 shows an embodiment of a preparation process for producing a polymer material mixed solution according to the disclosure. This preparation process corresponds to step S120 in FIG. 1.

First, as described in step S220, a polymer water-absorbing expansion material is mixed with water to produce a mixed intermediate. The polymer water-absorbing expansion material includes starch.

Then, as described in step S240, the mixed intermediate is gelatinized to produce a polymer material mixed solution.

Gelatinization refers to a process that after raw starch is added with water and heated, the crystalline form of the starch changes, and the volume and viscosity of starch granules increase to form a swelling state. This process is also referred to as α-gelatinization. In step S240, a heating manner is mainly used to induce a gelatinization reaction of the mixed intermediate produced in step S220.

Specifically, in an embodiment, in the above gelatinization step, the mixed intermediate is gradually heated to a preset temperature and stirred continuously until the mixed intermediate is pasty. The pasty product is the polymer material mixed solution produced in step S240. In an embodiment, the preset temperature is 100° C.

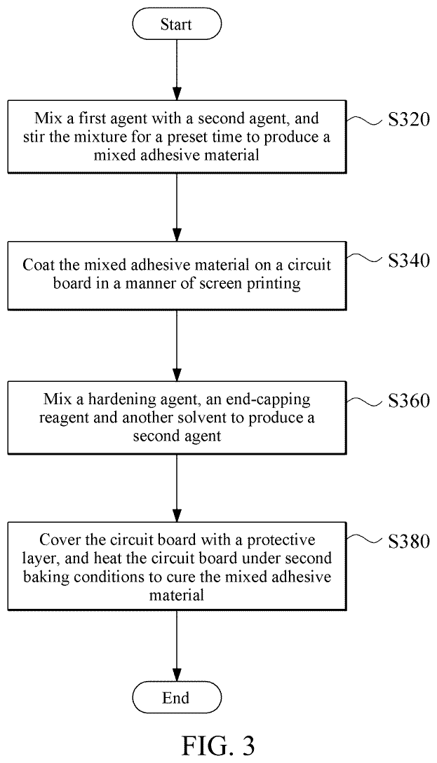

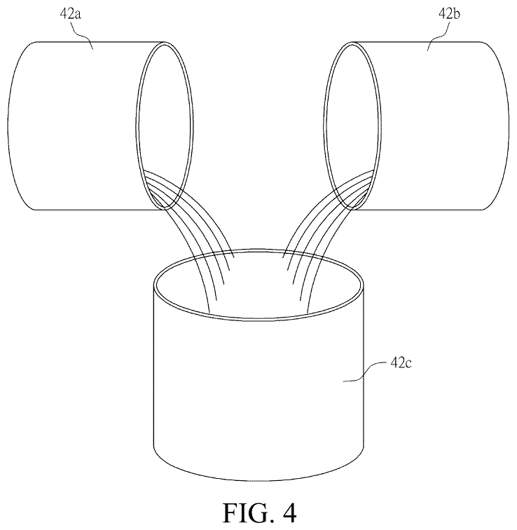

FIG. 3 is a flowchart of an application method of a waterproof adhesive provided in an embodiment of the disclosure. FIG. 4 to FIG. 7 are schematic diagrams corresponding to the steps of the application method shown in FIG. 3.

The application method is suitable for bonding a protective layer 44 to a circuit board 46 by a waterproof adhesive (including a first agent 42a and a second agent 42b) prepared by the preparation method in FIG. 1, so as to form a flexible circuit board 40. The flexible circuit board is applied to a keyboard, especially a membrane switch for a keyboard.

The application method includes the following steps.

First, as described in step S320, referring to FIG. 4 together, the first agent 42a is mixed with the second agent 42b, and the mixture of the first agent 42a and the second agent 42b is stirred for a preset time to produce a mixed adhesive material 42c.

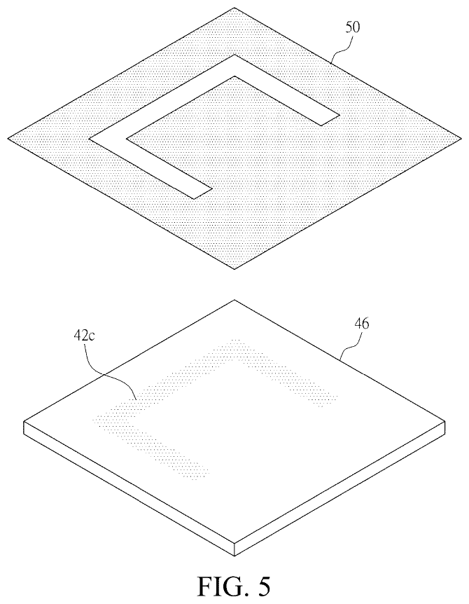

Then, as described in step S340, referring to FIG. 5 together, the mixed adhesive material 42c is coated on the circuit board 46 in a manner of screen printing by a screen 50 with preset patterns. In an embodiment, the mixed adhesive material 42c is coated on a surface of one side of the circuit board 46 with an exposed metallic circuit.

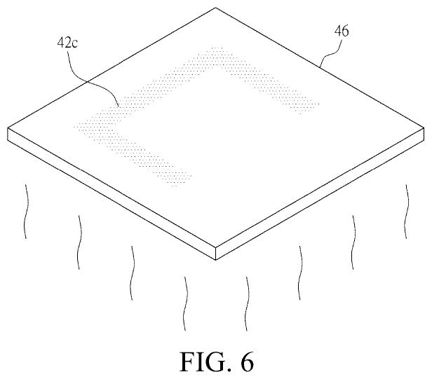

Then, as described in step S360, referring to FIG. 6 together, the circuit board 46 is heated under a first baking condition to shape the mixed adhesive material 42c. In an embodiment, the above the first baking condition is a baking temperature of 100-150° C. and a baking time of 6-30 s.

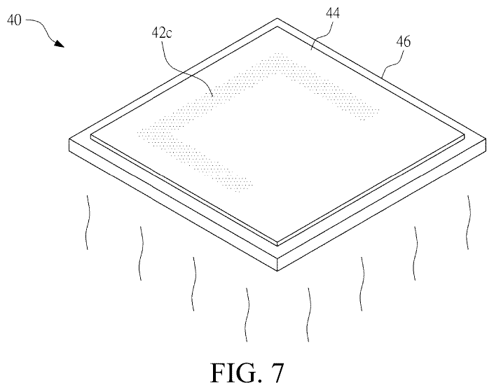

Then, as described in step S380, referring to FIG. 7 together, the circuit board 46 is covered with the protective layer 44 and heated under a second baking condition to cure the mixed adhesive material 42c, so that the protective layer 44 is bonded to the circuit board 46. The cured mixed adhesive material 42c provides a sealing effect to prevent water vapor from entering the space between the protective layer 44 and the circuit board 46 and causing oxidation of the metallic circuit.

In an embodiment, the above second baking condition is the baking temperature of 100-150° C. and the baking time of 10-30 min.

The waterproof adhesive provided by the disclosure compensates for shortcomings of existing waterproof adhesives. In application, only one printing step (i.e. reducing process steps) is needed to bond the protective layer 44 to the circuit board 46 and provide a sealing effect, thereby effectively solving the problem of key failure of a keyboard and reducing the cost burden caused by key failure of the keyboard.

Although the disclosure is disclosed above by way of embodiments, it is not intended to limit the disclosure. Those of ordinary skill in the art can make some variations and modifications without departing from the spirit and scope of the disclosure. Therefore, the protection scope of the disclosure is defined by the claims.

What is claimed is:

1. A waterproof adhesive suitable for a flexible circuit board, wherein the waterproof adhesive comprises:
a first agent, comprising a pressure sensitive adhesive and a polymer water-absorbing expansion material; and
a second agent, comprising a hardening agent and an end-capping reagent, wherein the first agent and the second agent are mixed for use.

2. The waterproof adhesive according to claim 1, wherein the polymer water-absorbing expansion material is selected from a group composed of hydrogenated cellulose, aquatic alginate, starch and combinations thereof.

3. The waterproof adhesive according to claim 1, wherein the first agent comprises a solvent.

4. The waterproof adhesive according to claim 3, wherein the solvent is selected from a group composed of ethylene glycol monobutyl ether acetate, polyvinyl alcohol, acrylic acid, isopropanol, ethyl acetate and combinations thereof.

5. The waterproof adhesive according to claim 3, wherein a hydrophilic-lipophilic balance (HLB) value of the solvent is 8-18.

6. The waterproof adhesive according to claim 1, wherein the hardening agent comprises cycloaliphatic amine and polyphenylmethane diisocyanate, and the end-capping reagent comprises isocyanate.

7. A preparation method of a waterproof adhesive, the waterproof adhesive comprising a first agent and a second agent, the first agent comprising a pressure sensitive adhesive and a polymer water-absorbing expansion material, the second agent comprising a hardening agent and an end-capping reagent, and the first agent and the second agent being mixed for use, wherein the preparation method comprises:
mixing the polymer water-absorbing expansion material with water to produce a polymer material mixed solution; and
adding the pressure sensitive adhesive and a solvent to the polymer material mixed solution to produce the first agent.

8. The preparation method of a waterproof adhesive according to claim 7, wherein the step of mixing the polymer water-absorbing expansion material with water to produce a polymer material mixed solution comprises:
mixing the polymer water-absorbing expansion material with water to produce a mixed intermediate; and
gelatinizing the mixed intermediate to produce the polymer material mixed solution,
wherein the polymer water-absorbing expansion material comprises starch.

9. An application method of a waterproof adhesive, suitable for bonding a protective layer to a circuit board, the waterproof adhesive comprising a first agent and a second agent, the first agent comprising a pressure sensitive adhesive and a polymer water-absorbing expansion material, and the second agent comprising a hardening agent and an end-capping reagent, wherein the application method comprises:
mixing the first agent with the second agent, and stirring a mixture of the first agent and the second agent for a preset time to produce a mixed adhesive material;
coating the mixed adhesive material on the circuit board in a manner of screen printing;
heating the circuit board under a first baking condition to shape the mixed adhesive material; and
covering the circuit board with the protective layer, and heating the circuit board under a second baking condition to cure the waterproof adhesive.

10. The application method of a waterproof adhesive according to claim 9, wherein the first baking condition is a baking temperature of 100-150° C. and a baking time is 6-30 s.

11. The application method of a waterproof adhesive according to claim 9, wherein the second baking condition is the baking temperature of 100-150° C. and the baking time of 10-30 min.
